(19) United States
(12) Patent Application Publication
(10) Pub. No.: US 2014/0078696 A1
(43) Pub. Date: Mar. 20, 2014

(54) ELECTRONIC DEVICE

(71) Applicant: KABUSHIKI KAISHA TOSHIBA, Tokyo (JP)

(72) Inventors: Takuya Matsuda, Kanagawa-ken (JP); Jun Morimoto, Kanagawa-ken (JP); Yuji Sasaki, Kanagawa-ken (JP)

(73) Assignee: Kabushiki Kaisha Toshiba, Tokyo (JP)

(21) Appl. No.: 13/833,075

(22) Filed: Mar. 15, 2013

(30) Foreign Application Priority Data
Sep. 20, 2012 (JP) 2012-207582

(51) Int. Cl. H05K 5/00

(52) U.S. Cl. CPC H05K 5/0017
USPC 361/752; 361/679.01

(57) ABSTRACT

According to one embodiment, an electronic device includes a display panel, an optical layer, an operation panel, a bonding layer, a first housing, and a second housing. The optical layer is provided on a display surface side of the display panel. The operation panel is adhered to the display panel. A peripheral portion of the operation panel protrudes sideward from the display panel. The bonding layer is provided on a side of the display panel opposite to the optical layer. The first housing includes containing and protruding portions. The protruding portion protrudes sideward from the containing portion to be adhered to the peripheral portion of the operation panel. The containing portion is adhered to the display panel. The second housing includes a bonding portion adhered to the peripheral portion of the operation panel. The second housing defines a containment space between the first and second housings.

### CROSS-REFERENCE TO RELATED APPLICATIONS

This application is based upon and claims the benefit of priority from the prior Japanese Patent Application No. 2012-207582, filed on Sep. 20, 2012; the entire contents of which are incorporated herein by reference.

### FIELD

Embodiments described herein relate generally to an electronic device.

### BACKGROUND

Electronic devices that have display panels include, for example, portable information devices that use flat display panels. In the case where glass is used as the material of the flat display panel and sensor unit to ensure rigidity in such a portable information device, the glass makes it difficult for the device to be thin and light.

### BRIEF DESCRIPTION OF THE DRAWINGS

FIG. 1 is a cross-sectional view illustrating an electronic device according to a first embodiment;

FIG. 2 is a cross-sectional view illustrating an electronic device according to a second embodiment and is a cross-sectional view of the electronic device when operated by the user; and

FIGS. 3A and 3B are plan views illustrating the bonding layer.

### DETAILED DESCRIPTION

According to one embodiment, an electronic device includes a display panel, an optical layer, an operation panel, a bonding layer, a first housing, and a second housing. The optical layer is provided on a display surface side of the display panel. The operation panel is adhered to the display panel with the optical layer interposed at a central portion of the operation panel. A peripheral portion of the operation panel protrudes sideward from the display panel. The bonding layer is provided on a side of the display panel opposite to the optical layer. The first housing includes a containing portion and a protruding portion. The protruding portion protrudes sideward from the containing portion to be adhered to the peripheral portion of the operation panel. The containing portion is adhered to the display panel with the bonding layer interposed. The containing portion is configured to contain the optical layer, the display panel, and the bonding layer. The second housing includes a bonding portion adhered to the peripheral portion of the operation panel with the protruding portion interposed. The second housing is formed around the peripheral portion of the operation panel to define a containment space between the first housing and the second housing.

Various embodiments will be described hereinafter in detail with reference to the accompanying drawings. The drawings are schematic or conceptual; and the relationships between the configurations and lengthwise and crosswise dimensions of portions, the proportions of sizes between portions, etc., are not necessarily the same as the actual values thereof. Further, the dimensions and/or the proportions may be illustrated differently between the drawings, even for identical portions. In the drawings and the specification of the application, components similar to those described in regard to a drawing thereinabove are marked with like reference numerals, and a detailed description is omitted as appropriate.

### First Embodiment

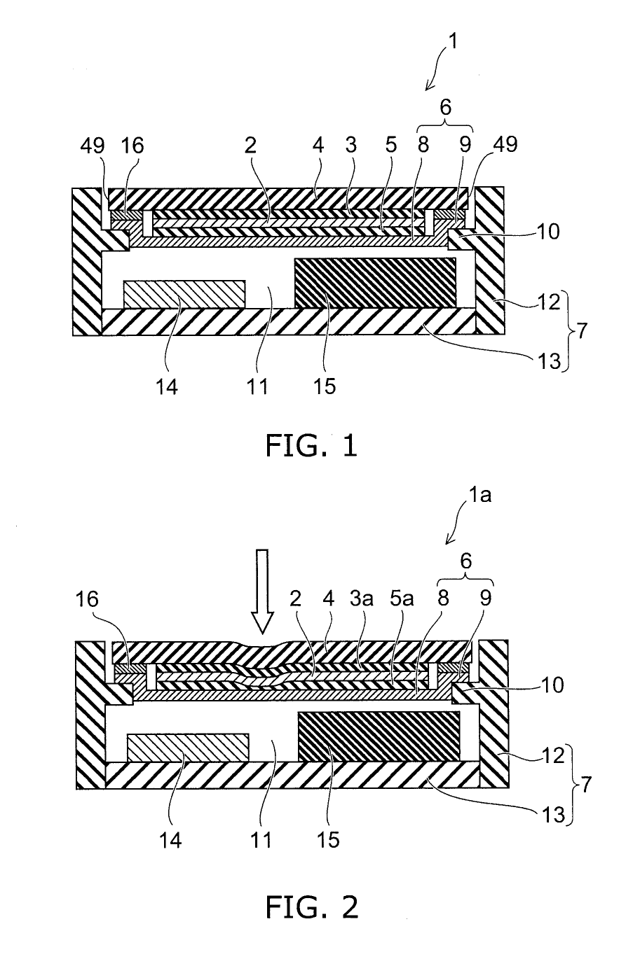

FIG. 1 is a cross-sectional view illustrating an electronic device according to a first embodiment.

The electronic device 1 of the embodiment is, for example, a portable terminal device and is formed in a thin substantially rectangular parallelepiped configuration.

The electronic device 1 includes a display panel 2, an optical layer 3, an operation panel 4, a bonding layer 5, a first housing 6, and a second housing 7.

The display panel 2 includes multiple pixels and includes, for example, an organic light-emitting diode (OLED). The display panel 2 functions as a display unit of the electronic device 1, displays output information to a user, and displays input information for, for example, a touch panel. The display panel 2 is flexible and is formed of, for example, a resin substrate having a thickness of 0.2 mm. For example, the display panel 2 may include the touch panel.

The optical layer 3 is made of a material having excellent transparency and is, for example, an acrylic or silicone adhesive or a transparent double-sided tape. The optical layer 3 is provided on the display surface side of the display panel 2 to bond and adhere the display panel 2 and the operation panel 4. The optical layer 3 optically couples the display panel 2 and the operation panel 4 and is formed with a thickness of, for example, 0.1 mm.

The operation panel 4 is, for example, a touch panel. The operation panel 4 together with the information displayed on the display panel 2 form the external appearance on the front surface side of the electronic device 1; and the operation panel 4 functions as an operation unit of the electronic device 1. The user performs input operations by pressing or touching the surface of the operation panel 4 with a finger, etc. In the case where the touch panel is a so-called externally-attached touch panel, the operation panel 4 includes a protective panel and a touch panel. In the case where the touch panel is a built-in touch panel that is built into the display panel 2, the operation panel 4 includes a protective panel.

The operation panel 4 is adhered to the display panel 2 with the optical layer 3 interposed at the central portion of the operation panel 4. The peripheral portion of the operation panel 4 protrudes sideward from the display panel 2. The operation panel 4 is formed of, for example, a resin having a thickness of 0.8 mm.

The bonding layer 5 includes, for example, a bonding agent, is provided on the side of the display panel 2 opposite to the optical layer 3, and bonds the display panel 2 to the first housing 6. It is sufficient for the bonding layer 5 to adhere the display panel 2 to the first housing 6; and, for example, at least a portion of the bonding layer 5 may be provided in contact with the display panel 2 and the first housing 6. Or, the bonding layer 5 may be provided in contact with the entire surface of the display panel 2. The bonding layer 5 may be, for example, a double-sided tape and may include a shock-absorbing material such as rubber, a sponge that includes, for example, a resin or the like, etc.

The first housing 6 is formed of, for example, a metal or an alloy including at least one selected from aluminum (Al), magnesium (Mg), and stainless steel (SUS) or a composite such as carbon-fiber-reinforced plastic (CFRP), etc. For example, the first housing 6 is formed in a plate configuration having a thickness of 0.2 mm to 0.5 mm such that the central portion is recessed with respect to the peripheral portion. The first housing 6 is more rigid than any one selected from the display panel 2, the optical layer 3, the operation panel 4, and the bonding layer 5. The first housing 6 includes a containing portion 8 that is recessed with respect to the peripheral portion, and a protruding portion 9 that protrudes sideward from the containing portion 8.

The containing portion 8 is adhered to the display panel 2 with the bonding layer 5 interposed and is configured to contain the display panel 2, the optical layer 3, and the bonding layer 5. The protruding portion 9 is provided around the containing portion 8, protrudes sideward from the containing portion 8, and is adhered to the lower surface of the peripheral portion of the operation panel 4 with, for example, a bonding layer 16 interposed. The bonding layer 16 may be made of a material similar to that of the bonding layer 5.

For example, the second housing 7 is formed of a resin, a magnesium (Mg) alloy, or a metal such as aluminum (Al) and the like, forms the external appearance of the side surface and the back surface of the electronic device 1, functions as a holder when held by the user, and contains a mounting substrate, a battery, etc., of the electronic device 1. The second housing 7 includes a bonding portion 10 that is adhered to the peripheral portion of the operation panel 4 with the protruding portion 9 of the first housing 6 interposed. The second housing 7 is provided around the peripheral portion of the operation panel 4 to define a containment space 11 between the first housing 6 and the second housing 7.

The second housing 7 may be more rigid than any one selected from the display panel 2, the optical layer 3, the operation panel 4, and the bonding layer 5.

The second housing 7 is disposed around an edge 4a of the periphery of the operation panel 4 to cover the edge 4a. Thereby, the edge 4a of the periphery of the operation panel 4 can be protected.

The protruding portion 9 and the bonding portion 10 are fixed by, for example, a bonding agent, screws, etc. In this specific example, the second housing 7 is formed of a front frame 12 that forms the side surface of the electronic device 1 and a rear frame 13 that forms the back surface of the electronic device 1.

The bonding portion 10 is provided in the front frame 12 of the first housing 6. The rear frame 13 is provided removably on the front frame 12 by, for example, a snap-fit.

For example, a mounting substrate 14 on which a circuit element configured to drive the display panel is mounted, a battery 15, etc., are provided in the containment space 11. The mounting substrate 14 and the battery 15 are adhered, for example, on the containment space 11 side of the rear frame 13 by double-sided tape. Because the rear frame 13 is provided removably on the front frame 12, the rear frame 13 can be removed from the front frame 12; and inspection of the mounting substrate 14 and replacement of the battery 15 can be performed.

Because resins are used as the display panel 2 and the operation panel 4 in the embodiment, the electronic device 1 can be thinner and lighter than in the case where glass is used.

For example, in the case where glass is used as at least one selected from the display panel 2 and the operation panel 4, the rigidity can be ensured; but the thickness is increased to prevent damage due to shocks; and the device cannot be thinner and lighter.

Conversely, in the embodiment, because the resins used as the display panel 2 and the operation panel 4 are more resilient to shocks than is glass, the resins can be thinner than glass while preventing damage; and the electronic device 1 can be thinner and lighter.

In the case where, for example, a clearance is provided by separating the display panel 2 from the first housing 6, the clearance makes it difficult for the device to be thin; and the rigidity of the device decreases.

Conversely, in the embodiment, resins are used as the display panel 2 and the operation panel 4; the display surface side of the display panel 2 is adhered to the operation panel 4 with the optical layer 3 interposed; the side of the display panel 2 opposite to the display surface is adhered to the first housing 6, which has a relatively high rigidity, with the bonding layer 5 interposed; and these are integrated. As a result, sufficient rigidity of the operation panel 4, the optical layer 3, the display panel 2, the bonding layer 5, and the first housing 6 can be ensured; bending when being ported by the user can be reduced; and the deformation amount occurring when being pressed by a finger when used can be reduced. Additionally, even in the case where the display panel 2 and the operation panel 4 of the embodiment are glass, damage can be prevented because the shocks can be mitigated by the integrated structure of the operation panel 4, the optical layer 3, the display panel 2, the bonding layer 5, and the first housing 6. Therefore, it is possible to use thinner glass.

Because the first housing 6 is adhered to the bonding portion 10 of the second housing 7 in the embodiment, sufficient rigidity of the operation panel 4 can be ensured even when the user holds the second housing 7 and operates the operation panel 4.

In this specific example, the lower surface of the protruding portion 9 of the first housing 6 is adhered to the upper surface and side surface of the bonding portion 10 of the front frame 12. As a result, the rigidity of the operation panel 4 when the user holds the front frame 12 and operates the operation panel 4 can be ensured; and the user can stably operate the operation panel 4.

In particular, in the case where the second housing 7 is more rigid than any one selected from the display panel 2, the optical layer 3, the operation panel 4, and the bonding layer 5, the rigidity of the operation panel 4 when the user holds the front frame 12 and operates the operation panel 4 can be ensured; and the user can stably operate the operation panel 4.

In the embodiment, the display panel 2, the optical layer 3, and the bonding layer 5 can be sealed airtightly in the containing portion 8 by the first housing 6 and the operation panel 4. As a result, for example, in the case where the display panel 2 includes an OLED, the life of the display panel 2 can be increased by preventing moisture entering from the outside and suppressing reactions between the water molecules and the organic light emitting element.

### Second Embodiment

FIG. 2 is a cross-sectional view illustrating an electronic device according to a second embodiment and is a cross-sectional view of the electronic device when operated by the user.

The configurations of the optical layer 3 and the bonding layer 5 of the electronic device 1a of the embodiment are different from those of the electronic device 1 of the first embodiment. In the electronic device 1a, an optical layer 3a and a bonding layer 5a are provided instead of the optical layer and the bonding layer 5 of the electronic device 1, respectively. Otherwise, the configuration of the embodiment is similar to the configuration of the first embodiment.

Compared to the optical layer 3 and the bonding layer 5, respectively, the rigidities of the optical layer 3a and the bonding layer 5a are set to be, for example, low; and the rigidities are adjusted to appropriately deform when the operation panel 4 is operated.

Generally, touch panels use various methods in which a conductive substance inside the touch panel does or does not deform when the user performs an operation, etc. For example, a so-called resistive touch panel includes an upper electrode and a lower electrode; and the position where the electrical resistance changes when the upper electrode is pressed down by the user using a finger, etc., is sensed. Therefore, it is desirable for the rigidity of at least one selected from the optical layer 3a and the bonding layer 5a to be set to be lower than that of the first housing 6 to deform when the operation panel 4 is pressed down.

As shown in FIG. 2, in the case where, for example, an input operation is performed by the user using a finger, etc., by pressing or touching the surface, the optical layer 3a and the bonding layer 5a can deform while the constant configuration of the first housing 6 can be maintained without deforming because the first housing 6 is more rigid than any one selected from the display panel 2, the optical layer 3a, the operation panel 4, and the bonding layer 5a. As a result, the user can be provided with an appropriate sense of depressibilty and resiliency; and the sense of operation can be improved.

On the other hand, a so-called capacitive touch panel senses the location touched by the user using a finger, etc., as the change of an electrostatic capacitance between electrodes. Therefore, it is desirable for the rigidities of the optical layer 3a and the bonding layer 5a to be set to be higher than in the case where the operation panel 4 is deformed by being pressed down according to the touch of the operation panel 4 and for the deformation when the operation panel 4 is pressed down to be small

In the embodiment, the rigidities of the optical layer 3a and the bonding layer 5a are adjusted according to the type of the operation panel 4; and at least one selected from the optical layer 3a and the bonding layer 5a deforms according to the operation of the operation panel 4. As a result, in addition to the effects of the first embodiment, the user can be provided with an appropriate sense of operation corresponding to the type of the operation panel 4 when the user performs an operation.

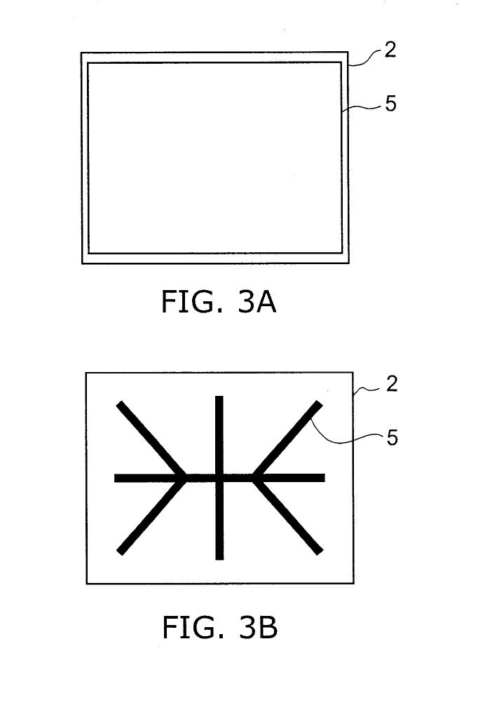

FIGS. 3A and 3B are plan views illustrating the bonding layer. FIG. 3A is a case where the bonding layer contacts the entire surface of the display panel; and FIG. 3B is a case where the bonding layer contacts a portion of the display panel in a radial configuration.

It is sufficient for the bonding layer 5 to adhere the display panel 2 to the first housing 6; and the bonding layer 5 may be provided on the entire surface of the display panel 2 as shown in FIG. 3A or in, for example, a radial configuration on a portion of the display panel 2 as shown in FIG. 3B.

Even in the case where the same material is used, the rigidity of the bonding layer 5 can be adjusted by the planar configuration of the bonding layer 5. For example, the rigidity can be relatively higher by providing the bonding layer 5 on the entire surface of the display panel 2; and the rigidity can be relatively lower by providing the bonding layer 5 on a portion of the display panel 2. Also, the bonding agent amount can be reduced by providing the bonding layer 5 on a portion of the display panel 2.

The planar configuration of the bonding layer 5 is not limited to the specific examples illustrated in FIGS. 3A and 3B; and various configurations may be used. Although the planar configurations illustrated in this specific example are for the bonding layer 5, this is similar for the bonding layer 5a.

Hereinabove, embodiments are described with reference to specific examples. However, the embodiments are not limited thereto; and various modifications are possible.

For example, in the electronic device 1, a configuration is illustrated in which the rear frame 13 of the second housing 7 is provided removably on the front frame 12. However, the second housing 7 may not include the front frame 12 and the rear frame 13; and it is sufficient for at least a portion of the second housing 7 to be provided removably.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An electronic device, comprising:
a display panel;
an optical layer provided on a display surface side of the display panel;
an operation panel adhered to the display panel with the optical layer interposed at a central portion of the operation panel, a peripheral portion of the operation panel protruding sideward from the display panel;
a bonding layer provided on a side of the display panel opposite to the optical layer;
a first housing including a containing portion and a protruding portion, the protruding portion protruding sideward from the containing portion to be adhered to the peripheral portion of the operation panel, the containing portion being adhered to the display panel with the bonding layer interposed, the containing portion being configured to contain the optical layer, the display panel, and the bonding layer; and
a second housing including a bonding portion adhered to the peripheral portion of the operation panel with the protruding portion interposed, the second housing being formed around the peripheral portion of the operation panel to define a containment space between the first housing and the second housing.

2. The device according to claim 1, wherein
the operation panel is a touch panel, and
at least one selected from the optical layer and the bonding layer is configured to deform according to an operation of the operation panel.

3. The device according to claim 1, wherein
the operation panel and the display panel include a resin, and
the optical layer and the bonding layer are configured to deform according to an operation of the operation panel.

4. The device according to claim 1, wherein the first housing is more rigid than any one selected from the display panel, the optical layer, the operation panel, and the bonding layer.

5. The device according to claim 1, wherein
a mounting substrate is provided on a side of the containment space of the second housing, a circuit element configured to drive the display panel being mounted on the mounting substrate, and
at least a portion of a portion of the second housing facing the first housing is provided removably.

6. The device according to claim 1, wherein the display panel is sealed airtightly in the containing portion.

7. The device according to claim 1, wherein the second housing is more rigid than any one selected from the display panel, the optical layer, the operation panel, and the bonding layer.

8. The device according to claim 1, wherein the bonding layer is provided on an entire surface of the display panel.

9. The device according to claim 1, wherein the bonding layer is provided on a portion of the display panel.

10. The device according to claim 1, wherein the second housing is disposed around an edge of a periphery of the operation panel to cover the edge.

11. An electronic device, comprising:
a display panel;
an operation panel adhered on a display surface side of the display panel, a peripheral portion of the operation panel protruding sideward from the display panel;
a first housing including a containing portion and a protruding portion, the containing portion being adhered to the display panel and configured to contain the display panel, the protruding portion protruding sideward from the containing portion to be adhered to the peripheral portion of the operation panel; and
a second housing including a bonding portion adhered to the peripheral portion of the operation panel with the protruding portion interposed, the second housing being formed around the peripheral portion of the operation panel to define a containment space between the first housing and the second housing.

12. The device according to claim 11, wherein
the display panel and the operation panel are adhered with an optical layer interposed,
the operation panel is a touch panel, and
the optical layer is configured to deform according to an operation of the operation panel.

13. The device according to claim 11, wherein
the display panel and the operation panel are adhered with an optical layer interposed;
the operation panel and the display panel include a resin; and
the optical layer is configured to deform according to an operation of the operation panel.

14. The device according to claim 11, wherein the first housing is more rigid than either selected from the display panel and the operation panel.

15. The device according to claim 11, wherein
a mounting substrate is provided on a side of the containment space of the second housing, a circuit element configured to drive the display panel being mounted on the mounting substrate, and
at least a portion of a portion of the second housing facing the first housing is provided removably.

16. The device according to claim 11, wherein the display panel is sealed airtightly in the containing portion.

17. The device according to claim 11, wherein the second housing is more rigid than either selected from the display panel and the operation panel.

18. The device according to claim 11, wherein
the display panel and the containing portion are adhered with a bonding layer interposed, and
the bonding layer is provided on an entire surface of the display panel.

19. The device according to claim 11, wherein
the display panel and the containing portion are adhered with a bonding layer interposed, and
the bonding layer is provided on a portion of the display panel.

20. The device according to claim 11, wherein the second housing is disposed around an edge of a periphery of the operation panel to cover the edge.
